(19) United States
(12) Patent Application Publication
(10) Pub. No.: US 2026/0155798 A1
(43) Pub. Date: Jun. 4, 2026

(54) DIFFERENTIAL INPUT/DIFFERENTIAL OUTPUT INVERTING AMPLIFIER CIRCUIT AND MEASURING DEVICE

(71) Applicant: HIOKI E.E. CORPORATION, Ueda-shi Nagano (JP)

(72) Inventors: Yuki KARASAWA, Ueda-shi Nagano (JP); Peiyu XIA, Ueda-shi Nagano (JP); Koki NAKAZAWA, Ueda-shi Nagano (JP); Kenta IKEDA, Ueda-shi Nagano (JP)

(21) Appl. No.: 19/123,254

(22) PCT Filed: Oct. 13, 2023
(86) PCT No.: PCT/JP2023/037184

§ 371 Date: Apr. 22, 2025

(30) Foreign Application Priority Data
Oct. 28, 2022 (JP) 2022-173219

(51) Int. Cl. H03F 3/45; G01R 19/00

(52) U.S. Cl. CPC H03F 3/45475; G01R 19/0046

(57) ABSTRACT

An inverting amplifier circuit including a signal input portion and a signal output portion, and the inverting amplifier circuit includes operational amplifiers OP1 to OP4, resistors R1 and R2 connected in series between the signal input portions, and a resistor R3 connected between a connection point P1 and an intermediate potential. The operational amplifier OP1 includes an inverting input terminal connected to the signal input portion via a resistor R4 and connected to an output terminal via a resistor R5 and a non-inverting input terminal connected to the connection point P1, and the output terminal is connected to the signal output portion. The operational amplifier OP2 includes an inverting input terminal connected to the signal input portion via a resistor R6 and connected to an output terminal via a resistor R7 and a non-inverting input terminal connected to the connection point P1.

### TECHNICAL FIELD

The present invention relates to a differential input/differential output inverting amplifier circuit for inputting a pair of differential input signals and inverting and amplifying the pair of differential input signals to be output as a pair of differential output signals, and a measuring device provided with the differential input/differential output inverting amplifier circuit for measuring a physical quantity.

### BACKGROUND ART

As a differential input/differential output inverting amplifier circuit for inputting a pair of differential input signals and inverting and amplifying the pair of differential input signals to be output as a pair of differential output signals, a differential input/differential output non-inverting amplifier circuit disclosed in the following patent document is known.

Hereinafter, part of FIG. 2 in the patent document will be extracted and described as FIG. 3. As illustrated in FIG. 3, the known non-inverting amplifier circuit 1X inputs a pair of differential input signals SINX+ and SINX− via signal input portions IS1X and IS2X and non-inverts and amplifies the pair of differential input signals SINX+ and SINX− to be output as a pair of differential output signals SOUTX+ and SOUTX− from signal output portions OS1X and OS2X.

Specifically, the non-inverting amplifier circuit 1X includes operational amplifiers OP1X and OP2X. In this case, the operational amplifier OP1X includes a non-inverting input terminal connected to the signal input portion IS1X, an inverting input terminal connected to an output terminal via a resistor R1X, and the output terminal is connected to the signal output portion OS1X. Further, the operational amplifier OP2X includes a non-inverting input terminal connected to the signal input portion IS2X, an inverting input terminal connected to an output terminal via a resistor R2X, and the output terminal is connected to the signal output portion OS2X. A resistor R3X is connected between the inverting input terminals of the operational amplifiers OP1X and OP2X.

In the non-inverting amplifier circuit 1X, the operational amplifier OP1X amplifies the differential input signal SINX+ that is one of the differential input signals SINX+ and SINX− with a predetermined gain to be output as the differential output signal SOUTX+ from the signal output portion OS1X. Further, the operational amplifier OP2X amplifies the differential input signal SINX− that is the other of the pair of the differential input signals SINX+ and SINX− with a predetermined gain to be output as the differential output signal SOUTX− from the signal output portion OS2X. According to the non-inverting amplifier circuit 1X, it is possible to configure a non-inverting amplifier circuit having excellent high-frequency characteristics with a simple configuration in which only two operational amplifiers are arranged symmetrically. By arranging two operational amplifiers symmetrically, an inverting amplifier circuit or a differential amplifier circuit can also be configured.

### CITATION LIST

### Patent Literature

Patent Document 1: JP 2020-25254 A (pages 16 to 48, FIG. 2)

### SUMMARY OF INVENTION

### Technical Problem

However, in the known non-inverting amplifier circuit 1X, although the non-inverting amplifier circuit having excellent high-frequency characteristics can be easily configured, since the two operational amplifiers are simply arranged symmetrically, there is an improvement in that when a high-frequency common-mode voltage is included in the differential input signals SINX+ and SINX−, the common-mode voltage cannot be removed.

The present invention has been made in view of such an improvement, and a main object thereof is to provide a differential input/differential output inverting amplifier circuit that can sufficiently remove the high-frequency common-mode voltage included in the differential input signal and output a differential output signal, and a measuring device including such a differential input/differential output inverting amplifier circuit.

### Solution to Problem

In order to achieve the above object, a differential input/differential output inverting amplifier circuit according to the present invention is a differential input/differential output inverting amplifier circuit configured to invert and amplify a pair of differential input signals input via a first signal input portion and a second signal input portion and output a pair of differential output signals from a first signal output portion and a second signal output portion. The inverting amplifier circuit includes a first operational amplifier, a second operational amplifier, a third operational amplifier, and a fourth operational amplifier, a first resistor and a second resistor connected in series between the first signal input portion and the second signal input portion, and a third resistor connected between a connection point of the first resistor and the second resistor and an intermediate potential. The first operational amplifier includes an inverting input terminal connected to the first signal input portion via a fourth resistor and connected to an output terminal via a fifth resistor and a non-inverting input terminal connected to the connection point via a first capacitor, and an output terminal is connected to the first signal output portion, the second operational amplifier includes an inverting input terminal connected to the second signal input portion via a sixth resistor and connected to an output terminal via a seventh resistor and a non-inverting input terminal connected to the connection point via a second capacitor, and an output terminal is connected to the second signal output portion, the third operational amplifier includes an inverting input terminal connected to the inverting input terminal of the first operational amplifier via an eighth resistor and connected to an output terminal via a third capacitor and a non-inverting input terminal connected to the intermediate potential, and an output terminal is connected to the non-inverting input terminal of the first operational amplifier via a ninth resistor, and the fourth operational amplifier includes an inverting input terminal connected to the inverting input terminal of the second operational amplifier via a tenth resistor and connected to the output terminal via a fourth capacitor and a non-inverting input terminal connected to the intermediate potential, and an output terminal is connected to the non-inverting input terminal of the second operational amplifier via an eleventh resistor.

According to the differential input/differential output inverting amplifier circuit, since the first operational amplifier to the fourth operational amplifier and the first resistor to the eleventh resistor are provided, the third operational amplifier is added to the first operational amplifier to form a composite amplifier, and the fourth operational amplifier is added to the second operational amplifier to form a composite amplifier, it is possible to remove the high-frequency common-mode voltage included in the pair of differential input signals and output the pair of differential output signals, and it is possible to improve low-frequency performance.

Further, in the differential input/differential output inverting amplifier circuit according to the present invention, resistance values of the first resistor and the second resistor are both defined as a value RX, a resistance value of the third resistor is defined as a value RY, resistance values of the fourth resistor and the sixth resistor are both defined as a value RA, resistance values of the fifth resistor and the seventh resistor are both defined as a value RB, and a relational expression of (RX=2×RY×(RA/RB)) is satisfied.

According to the differential input/differential output inverting amplifier circuit, since the resistance values of the first resistor to the seventh resistor are defined as described above, it is possible to sufficiently remove the high-frequency common-mode voltage included in the pair of differential input signals and output the pair of differential output signals, and it is possible to sufficiently improve the low-frequency performance.

Further, in the differential input/differential output inverting amplifier circuit according to the present invention, resistance values of the eighth resistor and the tenth resistor are defined to be equal to each other, resistance values of the ninth resistor and the eleventh resistor are defined to be equal to each other, capacitance values of the first capacitor and the second capacitor are defined to be equal to each other, and capacitance values of the third capacitor and the fourth capacitor are defined to be equal to each other.

According to the differential input/differential output inverting amplifier circuit, since the resistance values of the eighth resistor to the eleventh resistor and the capacitance values of the first capacitor to the fourth capacitor are defined as described above, it is possible to further sufficiently remove the high-frequency common-mode voltage included in the pair of differential input signals and output the pair of differential output signals, and it is possible to further sufficiently improve the low-frequency performance.

In order to achieve the above object, a differential input/differential output inverting amplifier circuit according to the present invention is a differential input/differential output inverting amplifier circuit configured to invert and amplify a pair of differential input signals input via a first signal input portion and a second signal input portion and output a pair of differential output signals from a first signal output portion and a second signal output portion. The inverting amplifier circuit includes a first operational amplifier and a second operational amplifier, a first resistor and a second resistor connected in series between the first signal input portion and the second signal input portion, and a third resistor connected between a connection point of the first resistor and the second resistor and an intermediate potential. The first operational amplifier includes an inverting input terminal connected to the first signal input portion via a fourth resistor and connected to an output terminal via a fifth resistor and a non-inverting input terminal connected to the connection point, and an output terminal is connected to the first signal output portion, and the second operational amplifier includes an inverting input terminal connected to the second signal input portion via a sixth resistor and connected to an output terminal via a seventh resistor and a non-inverting input terminal connected to the connection point, and an output terminal is connected to the second signal output portion.

According to the differential input/differential output inverting amplifier circuit, since the first operational amplifier, the second operational amplifier, and the first resistor to the seventh resistor are provided and configured as described above, it is possible to remove the high-frequency common-mode voltage included in the pair of differential input signals and output the pair of differential output signals.

Further, in the differential input/differential output inverting amplifier circuit according to the present invention, resistance values of the first resistor and the second resistor are both defined as a value RX, a resistance value of the third resistor is defined as a value RY, resistance values of the fourth resistor and the sixth resistor are both defined as a value RA, resistance values of the fifth resistor and the seventh resistor are both defined as a value RB, and a relational expression of (RX=2×RY×(RA/RB)) is satisfied.

According to the differential input/differential output inverting amplifier circuit, since the resistance values of the first resistor to the seventh resistor are defined as described above, it is possible to sufficiently remove the high-frequency common-mode voltage included in the pair of differential input signals and output the pair of differential output signals.

Further, in order to achieve the above object, a measuring device according to the present invention includes any one of the differential input/differential output inverting amplifier circuits described above, and measures a physical quantity based on the pair of differential output signals output from the differential input/differential output inverting amplifier circuit.

According to the measuring device, by measuring a physical quantity based on the pair of differential output signals from which the high-frequency common-mode voltage is removed, the physical quantity can be accurately measured.

### Advantageous Effects of Invention

According to a differential input/differential output inverting amplifier circuit of the present invention, it is possible to sufficiently remove a high-frequency common-mode voltage included in a pair of differential input signals and output a pair of differential output signals. In addition, according to the measuring device of the present invention, the physical quantity can be accurately measured.

### BRIEF DESCRIPTION OF DRAWINGS

FIG. 1 is a circuit diagram of an inverting amplifier circuit 1.

FIG. 2 is a circuit diagram of an inverting amplifier circuit 1A.

FIG. 3 is a circuit diagram of a known non-inverting amplifier circuit 1X.

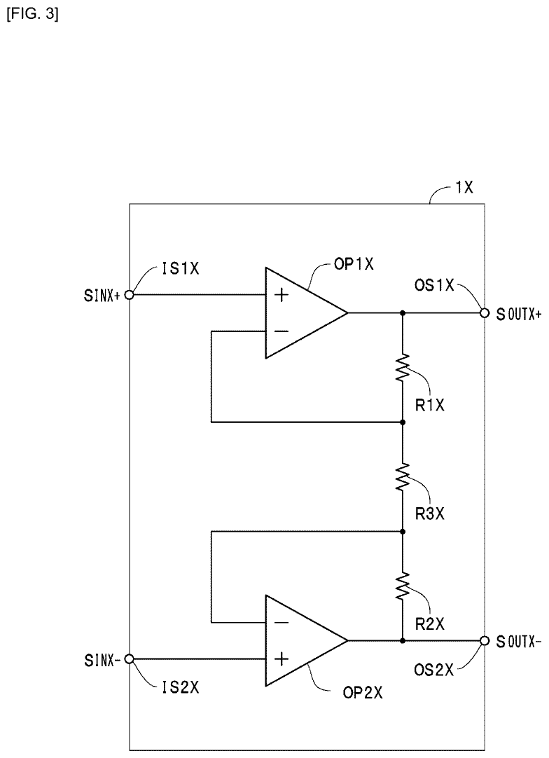

### DESCRIPTION OF EMBODIMENTS

Hereinafter, embodiments of a measuring device and a differential input/differential output inverting amplifier circuit will be described with reference to the accompanying drawings.

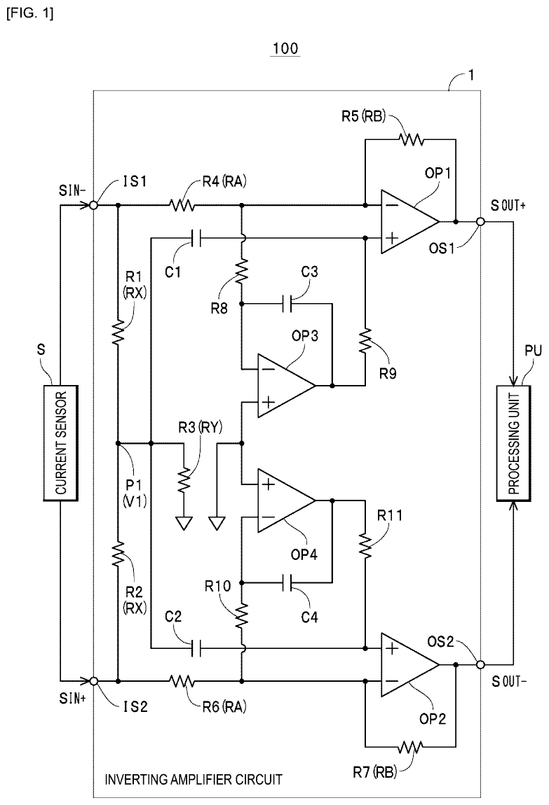

A measuring device 100 illustrated in FIG. 1 includes a current sensor S, an inverting amplifier circuit 1, and a processing unit PU, and is configured to be able to measure a current as a physical quantity.

The current sensor S is, as an example, a current sensor disclosed in JP 2014-215065 A that is configured with a current sensor for detecting a current value of a current flowing through a detection conductor (electric wire to be measured) by a zero flux method (a method including a core, a magneto-electric conversion part (Hall element, flux gate element, etc.), a feedback winding, a voltage-current conversion circuit, a detection resistance circuit for converting a negative feedback current into a voltage and outputting the voltage, and an amplifier circuit for amplifying a voltage output from the detection resistance circuit and outputting the voltage as an output voltage) and detects the current flowing through the detection conductor and outputs the current as a pair of differential input signals SIN− and SIN+. However, not limited to this configuration, a current sensor having any configuration can be employed. In addition, the current sensor S may be configured as a clamp type that can clamp the detection conductor.

The inverting amplifier circuit 1 is configured to function as a differential input/differential output inverting amplifier circuit that inputs the pair of differential input signals SIN− and SIN+ output from the current sensor S via the signal input portion IS1 (first signal input portion) and the signal input portion IS2 (second signal input portion), inverts and amplifies the pair of differential input signals SIN− and SIN+, and outputs the pair of differential output signals SOUT+ and SOUT− from the signal output portion OS1 (first signal output portion) and the signal output portion OS2 (second signal output portion) to the processing unit PU.

Specifically, the inverting amplifier circuit 1 includes an operational amplifier OP1 having good high-frequency characteristics (for example, good broadband characteristics) functioning as a first operational amplifier, an operational amplifier OP2 having good high-frequency characteristics (for example, good broadband characteristics) functioning as a second operational amplifier, an operational amplifier OP3 having good low-frequency characteristics functioning as a third operational amplifier, and an operational amplifier OP4 having good low-frequency characteristics functioning as a fourth operational amplifier. In this case, each of the operational amplifiers OP1 to OP4 operates for example, a positive voltage and a negative voltage as power supply voltages whose absolute values are equal to each other with respect to a ground potential as an intermediate potential.

The inverting amplifier circuit 1 amplifier circuit 1 includes a resistor R1 functioning as a first resistor and a resistor R2 functioning as a second resistor which are connected in series between the signal input portion IS1 and the signal input portion IS2, and a resistor R3 functioning as a third resistor which is connected between a mutual connection point P1 of the resistor R1 and the resistor R2 and an intermediate potential.

The operational amplifier OP1 includes an inverting input terminal (first inverting input terminal) connected to the signal input portion IS1 via a resistor R4 (fourth resistor) and connected to an output terminal (first output terminal) via a resistor R5 (fifth resistor) and a non-inverting input terminal (first non-inverting input terminal) connected to the connection point P1 via a capacitor C1 (first capacitor), and the output terminal (first output terminal) is connected to the signal output portion OS1. The operational amplifier OP2 includes an inverting input terminal (second inverting input terminal) connected to the signal input portion IS2 via a resistor R6 (sixth resistor) and connected to an output terminal (second output terminal) via a resistor R7 (seventh resistor) and a non-inverting input terminal (second non-inverting input terminal) connected to the connection point P1 via a capacitor C2 (second capacitor), and the output terminal (second output terminal) is connected to the signal output portion OS2.

The operational amplifier OP3 includes an inverting input terminal (third inverting input terminal) connected to the inverting input terminal of the operational amplifier OP1 via the resistor R8 (eighth resistor) and connected to an output terminal (third output terminal) via a capacitor C3 (third capacitor) and a non-inverting input terminal (third non-inverting input terminal) connected to the intermediate potential, and the output terminal (third output terminal) is connected to the non-inverting input terminal of the operational amplifier OP1 via a resistor R9 (ninth resistor). The operational amplifier OP4 includes an inverting input terminal (fourth inverting input terminal) connected to the inverting input terminal of the operational amplifier OP2 via a resistor R10 (tenth resistor) and connected to an output terminal (fourth output terminal) via a capacitor C4 (fourth capacitor) and a non-inverting input terminal (fourth non-inverting input terminal) connected to the intermediate potential, and the output terminal (fourth output terminal) is connected to the non-inverting input terminal of the operational amplifier OP2 via a resistor R11 (eleventh resistor).

In this case, in the inverting amplifier circuit 1, the resistance values of the resistors R1 and R2 are both defined as a value RX, the resistance value of the resistor R3 is defined as the value RY, the resistance values of the resistors R4 and R6 are both defined as a value RA, the resistance values of the resistors R5 and R7 are both defined as a value RB, and a relational expression of (RX=2×RY×(RA/RB)) is satisfied, and the resistance values of the resistors R8 and R10 are defined to be equal to each other, the resistance values of the resistors R9 and R11 are defined to be equal to each other, the capacitance values of the capacitors C1 and C2 are defined to be equal to each other, and the capacitance values of the capacitors C3 and C4 are defined to be equal to each other.

The processing unit PU measures the current value of the current flowing through the detection conductor based on the pair of differential output signals SOUT+ and SOUT− output from the signal output portions OS1 and OS2, respectively, of the inverting amplifier circuit 1. Specifically, the processing unit PU samples the pair of differential output signals SOUT+ and SOUT− to generate waveform data, and measures the current value of the current flowing through the detection conductor based on the waveform data. Further, the processing unit PU outputs current value data indicating the measured current value to a display unit or a storage unit (not illustrated) to display the current value on the display unit or store the current value in the storage unit.

Next, operations of the measuring device 100 and the inverting amplifier circuit 1 will be described.

First, the operation of the inverting amplifier circuit 1 when the differential input signals SIN− and SIN+ output from the current sensor S are signals having high-frequency (hereinafter also referred to as “high-frequency signals”) will be described. When the differential input signals SIN− and SIN+ are the high-frequency signals, the impedance of the capacitors C1 and C2 becomes extremely small, and thus the inverting amplifier circuit 1 equivalently has a circuit configuration in which the connection point P1 and the non-inverting input terminal of the operational amplifier OP1 are short-circuited, and the connection point P1 and the non-inverting input terminal of the operational amplifier OP2 are short-circuited. Further, in the inverting amplifier circuit 1, the impedance of the capacitors C3 and C4 becomes extremely small, and thus the inverting amplifier circuit 1 equivalently has a circuit configuration in which the operational amplifiers OP3 and OP4 do not function.

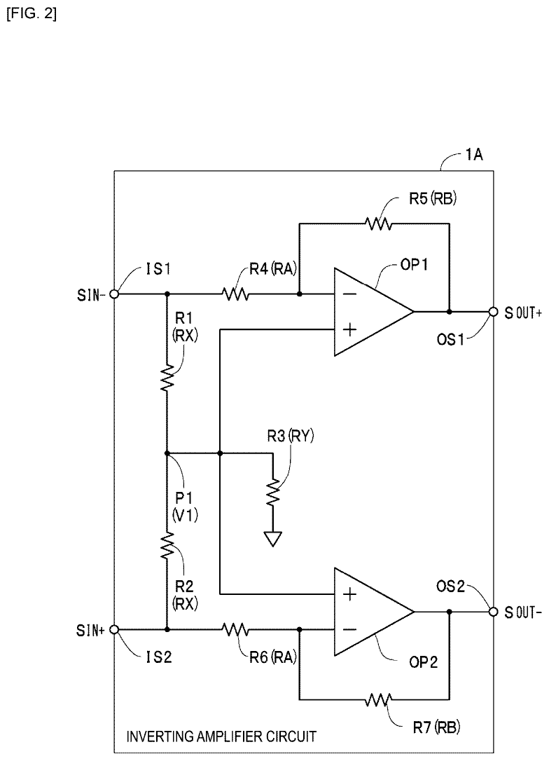

Thus, as illustrated in FIG. 2, when the differential input signals SIN− and SIN+ are the high-frequency signals, the inverting amplifier circuit 1 is equivalently represented as an inverting amplifier circuit 1A. Thus, in the inverting amplifier circuit 1A, the operational amplifier OP1 includes an inverting input terminal connected to the signal input portion IS1 via a resistor R4 and connected to the output terminal via the resistor R5 and a non-inverting input terminal connected to the connection point P1 and the output terminal is connected to the signal output portion OS1. In the inverting amplifier circuit 1A, the operational amplifier OP2 includes an inverting input terminal connected to the signal input portion IS2 via the resistor R6 and connected to the signal output terminal via the resistor R7 and a non-inverting input terminal connected to the connection point P1, and the output terminal is connected to the signal output portion OS2. In FIG. 2, illustration of the current sensor S and the processing unit PU is omitted.

In the inverting amplifier circuit 1A, a voltage V1 at the connection point P1 is expressed by the following Equation (1), where VCM is the voltage value of the high-frequency common-mode voltage superimposed on the differential input signal SIN−.

$$V 1 = VCM / ( 1 + ( RX / ( 2 \times RY ) ) ) \qquad Equation ( 1 )$$

When open loop gains of the operational amplifiers OP1 and OP2 are sufficiently large, a voltage value VOUT+ of the differential output signal SOUT+ is expressed by the following Equation (2). Hereinafter, a voltage value of the differential input signal SIN− is referred to as VIN−, and voltage values of the differential output signals SOUT+ and SOUT− are referred to as VOUT+ and VOUT−, respectively.

$${VOUT}_{+} = - ( RB / RA ) \times {VIN}_{-} + ( 1 + ( RB / RA ) ) \times V 1 \qquad Equation ( 2 )$$

Here, in order to cancel the high-frequency common-mode voltage superimposed on the differential input signal SIN−, it is necessary to set the voltage value VOUT+ to 0 V when the voltage value VIN− is the voltage value VCM, and thus the following Equation (3) is derived from the above Equation (2).

$$( RB / RA ) \times {VIN}_{-} = ( 1 + RB / RA ) \times V 1 \qquad Equation ( 3 )$$

The following Equation (4) is derived from Equations (1) and (3).

$$RX = 2 \times RY \times ( RB / RA ) \qquad Equation ( 4 )$$

Similarly, when the high-frequency common-mode voltage having the voltage value VCM is superimposed on the differential input signal SIN+, the voltage value of the high-frequency common-mode voltage included in the differential output signal SOUT− becomes 0 V when the above Equation (4) is satisfied.

That is, even when the high-frequency common-mode voltage is superimposed on the pair of differential input signals SIN− and SIN+, when the resistance values of the resistors R1 and R2 are both defined as the value RX, the resistance value of the resistor R3 is defined as the value RY, the resistance values of the resistors R4 and R6 are both defined as the value RA, and the resistance values of the resistors R5 and R7 are both defined as the value RB, and the resistance values of each of the resistors R1 to R7 are defined so as to satisfy the relational expression of Equation (4) (RX=2×RY×(RA/RB)), the voltage value of the high-frequency common-mode voltage included in the pair of differential output signals SOUT+ and SOUT− can be set to 0 V. In other words, according to the inverting amplifier circuit 1A, the common mode rejection ratio can be sufficiently improved.

Since the differential input signal components of the pair of differential input signals SIN− and SIN+ have absolute values equal to each other and opposite polarities, the voltage value VIN− becomes the voltage value −VIN+, so that the voltage V1 at the connection point P1 becomes 0 V. Thus, the gains of the inverting amplifier circuit 1A with respect to the differential input signal components of the pair of differential input signals SIN− and SIN+ are expressed by the following Equations (5) and (6). As a result, even when the resistance values are defined so as to satisfy the relational expression of Equation (4), the gain with respect to the differential input signal components of the pair of differential input signals SIN− and SIN+ is not affected.

$${VOUT}_{+} = - ( RB / RA ) \times {VIN}_{-} \qquad Equation ( 5 )$$

$${VOUT}_{-} = - ( RB / RA ) \times {VIN}_{+} \qquad Equation ( 6 )$$

As described above, according to the inverting amplifier circuit 1A, since the resistance values of the resistors R1 to R7 are defined so as to satisfy Equation (4), it is possible to sufficiently remove the high-frequency common-mode voltage included in the pair of differential input signals SIN− and SIN+ and output the pair of differential output signals SOUT+ and SOUT−.

Next, with reference to FIG. 1, the operation of the inverting amplifier circuit 1 when the differential input signals SIN− and SIN+ are DC signals or signals having a sufficiently low frequency (hereinafter, both are also collectively referred to as “DC signals”) will be described.

As illustrated in FIG. 1, when the differential input signals SIN− and SIN+ are the DC signals, since the impedance of the capacitors C1 and C3 is extremely large, the inverting amplifier circuit 1 forms a composite inverting amplifier circuit by adding the operational amplifier OP3 having good low-frequency characteristics to the operational amplifier OP1, and forms a composite inverting amplifier circuit by adding the operational amplifier OP4 having good low-frequency characteristics to the operational amplifier OP2.

In this case, the operational amplifier OP3 improves the low-frequency characteristics of the operational amplifier OP1, and the operational amplifier OP4 improves the low-frequency characteristics of the operational amplifier OP2. Specifically, the operational amplifier OP3 inverts and amplifies the voltage at the inverting input terminal of the operational amplifier OP1 with a high gain and feeds it forward to the non-inverting input terminal of the operational amplifier OP1, thereby performing a negative-feedback operation to cancel an offset voltage and a 1/f noise generated between the inverting and non-inverting input terminals of the operational amplifier OP1 and reducing the offset voltage and the 1/f noise. Thus, the low-frequency characteristics of the operational amplifier OP1 are compensated by the operational amplifier OP3 having good low-frequency characteristics, and the low-frequency characteristics of the operational amplifier OP1 are sufficiently improved. Further, the operational amplifier OP4 inverts and amplifies the voltage at the inverting input terminal of the operational amplifier OP2 with a high gain and feeds it forward to the non-inverting input terminal of the operational amplifier OP2, thereby performing a negative-feedback operation to cancel an offset voltage and a 1/f noise generated between the inverting and non-inverting input terminals of the operational amplifier OP2 and reducing the offset voltage and the 1/f noise. Thus, the low-frequency characteristics of the operational amplifier OP2 are compensated by the operational amplifier OP4 having good low-frequency characteristics, and the low-frequency characteristics of the operational amplifier OP2 are sufficiently improved. The gains of the inverting amplifier circuit 1 with respect to the differential input signal components when the differential input signals SIN− and SIN+ are the DC signals are expressed by the above-described Equations (5) and (6).

Next, in the measuring device 100, the processing unit PU measures the current value of the current flowing through the detection conductor as described above based on the pair of differential output signals SOUT+ and SOUT− output from the inverting amplifier circuit 1 (inverting amplifier circuit 1A). Further, the processing unit PU outputs current value data indicating the measured current value to a display unit or a storage unit (not illustrated) to display the current value on the display unit or store the current value in the storage unit.

As described above, according to the inverting amplifier circuit 1, since the operational amplifiers OP1 to OP4 and the resistors R1 to R11 are provided, and the operational amplifier OP3 having good low-frequency characteristics is added to the operational amplifier OP1 having good high-frequency characteristics to form the composite amplifier, and the operational amplifier OP4 having good low-frequency characteristics is added to the operational amplifier OP2 having good high-frequency characteristics to form the composite amplifier, it is possible to remove the high-frequency common-mode voltage included in the pair of differential input signals SIN− and SIN+ and output the pair of differential output signals SOUT+ and SOUT−, and it is possible to improve the low-frequency performance.

Further, according to the inverting amplifier circuit 1, since the resistance values of the resistors R1 to R7 are defined as described above, it is possible to sufficiently remove the high-frequency common-mode voltage included in the pair of differential input signals SIN− and SIN+ and output the pair of differential output signals SOUT+ and SOUT−, and it is possible to sufficiently improve the low-frequency performance.

According to the inverting amplifier circuit 1, since the resistance values of the resistors R8 to R11 and the capacitance values of the capacitors C1 to C4 are defined as described above, it is possible to further sufficiently remove the high-frequency common-mode voltage included in the pair of differential input signals SIN− and SIN+ and output the pair of differential output signals SOUT+ and SOUT−, and it is possible to further sufficiently improve the low-frequency performance.

In addition, according to the measuring device 100 described above, by measuring the physical quantity (current value in the present example) based on the pair of differential output signals SOUT+ and SOUT− from which the high-frequency common-mode voltage is removed, the physical quantity can be accurately measured.

It should be noted that the present invention is not limited to the above-described embodiments and can be modified as appropriate. For example, when the operational amplifiers OP1 and OP2 are required to reduce the high-frequency common-mode voltage in preference to good low-frequency characteristics, the configuration of the inverting amplifier circuit 1A described above with reference to FIG. 2 can be employed without using the operational amplifiers OP3 and OP4, the resistors R8 to R11, and the capacitors C1 to C4.

According to the inverting amplifier circuit 1A, since the operational amplifiers OP1 and OP2 and the resistors R1 to R7 as described above are provided, it is possible to remove the high-frequency common-mode voltage included in the pair of differential input signals SIN− and SIN+ and output the pair of differential output signals SOUT+ and SOUT−.

In addition, according to the inverting amplifier circuit 1A, since the resistance values of the resistors R1 to R7 are defined as described above, it is possible to sufficiently remove the high-frequency common-mode voltage included in the pair of differential input signals SIN− and SIN+ and output the pair of differential output signals SOUT+ and SOUT−.

According to the measuring device 100 including the inverting amplifier circuit 1A, by measuring the physical quantity based on the pair of differential output signals from which the high-frequency common-mode voltage is removed, the physical quantity can be accurately measured.

Further, in the inverting amplifier circuit 1, the resistance values of the resistors R8 and R10 are defined to be equal to each other, the resistance values of the resistors R9 and R11 are defined to be equal to each other, the capacitance values of the capacitors C1 and C2 are defined to be equal to each other, and the capacitance values of the capacitors C3 and C4 are defined to be equal to each other. However, with respect to these resistors and capacitors, some errors and differences can be allowed. In order to increase the common-mode rejection ratio as large as possible in the inverting amplifier circuits 1 and 1A, it is most preferable that the resistance values of the resistors R1 and R2 are defined to be as equal as possible to each other, the resistance values of the resistors R4 and R6 are defined to be as equal as possible to each other, and the resistance values of the resistors R5 and R7 are defined to be as equal as possible to each other. However, as long as the common mode rejection ratio of a desired magnitude can be obtained, an error with respect to the resistance value of each resistor can be allowed.

In the above-described embodiment, the example in which the inverting amplifier circuit 1 is applied to the measuring device 100 that measures a current has been described. However, not limited thereto, the inverting amplifier circuit 1 can be applied to a measuring device that measures various physical quantities such as a voltage, a temperature, a pressure, and light.

### INDUSTRIAL APPLICABILITY

According to the present invention, it is possible to sufficiently remove the high-frequency common-mode voltage included in a pair of differential input signals and output a pair of differential output signals. Thus, the present invention can be widely applied to such a differential input/differential output inverting amplifier circuit and a measuring device including such a differential input/differential output inverting amplifier circuit.

### REFERENCE SIGNS LIST

100 Measuring device
1, 1A Inverting amplifier circuit
C1 to C4 Capacitor
IS1, IS2 Signal input portion
OS1, OS2 Signal output portion
OP1 to OP4 Operational amplifier
P1 Connection point
R1 to R11 Resistor
SIN−, SIN+ Differential input signal
SOUT+, SOUT− Differential output signal

1. A differential input/differential output inverting amplifier circuit configured to invert and amplify a pair of differential input signals input via a first signal input portion and a second signal input portion and output a pair of differential output signals from a first signal output portion and a second signal output portion, the inverting amplifier circuit comprising:
a first operational amplifier, a second operational amplifier, a third operational amplifier, and a fourth operational amplifier;
a first resistor and a second resistor connected in series between the first signal input portion and the second signal input portion; and
a third resistor connected between a connection point of the first resistor and the second resistor and an intermediate potential, wherein
the first operational amplifier includes an inverting input terminal connected to the first signal input portion via a fourth resistor and connected to an output terminal via a fifth resistor and a non-inverting input terminal connected to the connection point via a first capacitor, and an output terminal is connected to the first signal output portion,
the second operational amplifier includes an inverting input terminal connected to the second signal input portion via a sixth resistor and connected to an output terminal via a seventh resistor and a non-inverting input terminal connected to the connection point via a second capacitor, and an output terminal is connected to the second signal output portion,
the third operational amplifier includes an inverting input terminal connected to the inverting input terminal of the first operational amplifier via an eighth resistor and connected to an output terminal via a third capacitor and a non-inverting input terminal connected to the intermediate potential, and an output terminal is connected to the non-inverting input terminal of the first operational amplifier via a ninth resistor,
the fourth operational amplifier includes an inverting input terminal connected to the inverting input terminal of the second operational amplifier via a tenth resistor and connected to the output terminal via a fourth capacitor and a non-inverting input terminal connected to the intermediate potential, and an output terminal is connected to the non-inverting input terminal of the second operational amplifier via an eleventh resistor.

2. The differential input/differential output inverting amplifier circuit according to claim 1, wherein
resistance values of the first resistor and the second resistor are both defined as a value RX,
a resistance value of the third resistor is defined as a value RY,
resistance values of the fourth resistor and the sixth resistor are both defined as a value RA,
resistance values of the fifth resistor and the seventh resistor are both defined as a value RB, and
a relational expression of (RX=2×RY×(RA/RB)) is satisfied.

3. The differential input/differential output inverting amplifier circuit according to claim 2, wherein
resistance values of the eighth resistor and the tenth resistor are defined to be equal to each other,
resistance values of the ninth resistor and the eleventh resistor are defined to be equal to each other,
capacitance values of the first capacitor and the second capacitor are defined to be equal to each other, and
capacitance values of the third capacitor and the fourth capacitor are defined to be equal to each other.

4. A differential input/differential output inverting amplifier circuit configured to invert and amplify a pair of differential input signals input via a first signal input portion and a second signal input portion and output a pair of differential output signals from a first signal output portion and a second signal output portion, the inverting amplifier circuit comprising:
a first operational amplifier and a second operational amplifier;
a first resistor and a second resistor connected in series between the first signal input portion and the second signal input portion; and
a third resistor connected between a connection point of the first resistor and the second resistor and an intermediate potential, wherein
the first operational amplifier includes an inverting input terminal connected to the first signal input portion via a fourth resistor and connected to an output terminal via a fifth resistor and a non-inverting input terminal connected to the connection point, and an output terminal is connected to the first signal output portion, and
the second operational amplifier includes an inverting input terminal connected to the second signal input portion via a sixth resistor and connected to an output terminal via a seventh resistor and a non-inverting input terminal connected to the connection point, and an output terminal is connected to the second signal output portion.

5. The differential input/differential output inverting amplifier circuit according to claim 4, wherein
resistance values of the first resistor and the second resistor are both defined as a value RX,
a resistance value of the third resistor is defined as a value RY,
resistance values of the fourth resistor and the sixth resistor are both defined as a value RA,
resistance values of the fifth resistor and the seventh resistor are both defined as a value RB, and
a relational expression of (RX=2×RY×(RA/RB)) is satisfied.

6. A measuring device comprising:
the differential input/differential output inverting amplifier circuit according to claim 1, wherein the measuring device measures a physical quantity based on the pair of differential output signals output from the differential input/differential output inverting amplifier circuit.
